(19) United States
(12) Patent Application Publication
(10) Pub. No.: US 2010/0181664 A1
(43) Pub. Date: Jul. 22, 2010

(54) INTEGRATED CIRCUIT CHIP PACKAGE MODULE

(75) Inventors: FANG-TA TAI, Tu-Cheng (TW); CHEN-HSIANG LIN, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/400,793

(22) Filed: Mar. 9, 2009

(30) Foreign Application Priority Data
Jan. 16, 2009 (CN) 200910300247.4

(51) Int. Cl. H01L 23/40

(52) U.S. Cl. 257/713; 257/E23.084

(57) ABSTRACT

An integrated circuit (IC) package module includes a carrier, an IC chip, a number of wires, a number of pins, a seal member, and a thermal conductor. The IC chip is attached on a top surface of the carrier. The number of pins is connected to the IC chip via the number of wires. The seal member contains the carrier, the IC chip, and the number of wires. The thermal conductor is located over or located on a top surface of the IC chip. Parts of each of the number of pins and the thermal conductor are projected out of the seal member.

### BACKGROUND

1. Technical Field

Embodiments of the present disclosure relate to package modules and, more particularly, to an integrated circuit (IC) chip package module.

2. Description of the Related Art

All levels of package modules (chips, electronic circuit assembly, and systems) are becoming more and more miniaturized. A major technical challenge is thermal dissipation as power density increases due to the miniaturization of the package modules. Ordinarily, heat from an IC chip package module is transferred to a printed circuit board via a plurality of leads of the IC chip package module which are connected to the printed circuit board. However, if heat from the IC package module is great, the sizes of the leads may be not big enough to radiate heat effectively. As a result, the IC chip package module may run the risk of be overheated.

### BRIEF DESCRIPTION OF THE DRAWINGS

FIG. 1 is an isometric view of an embodiment of an IC chip package module.

FIG. 2 is a sectional view taken along the line II-II of FIG. 1.

FIG. 3 is a sectional view of another embodiment of an IC chip package module.

### DETAILED DESCRIPTION

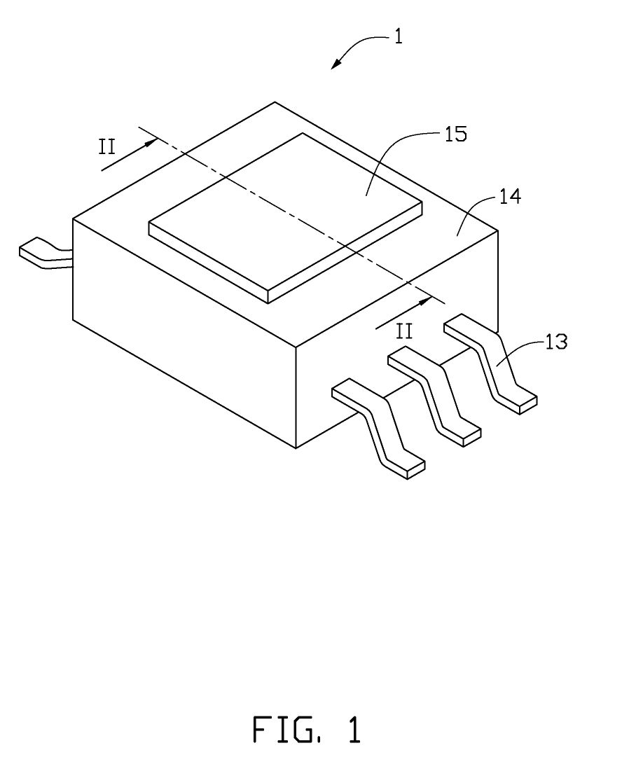

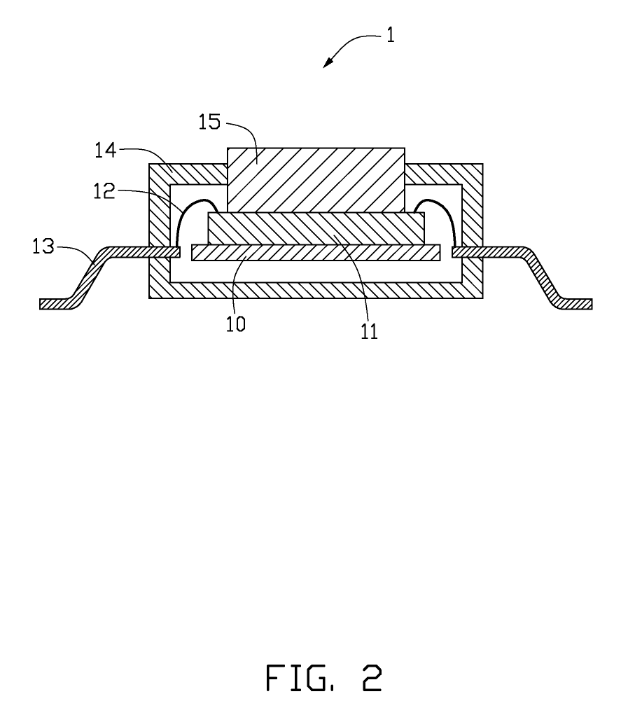

Referring to FIGS. 1-2, one embodiment of an integrated circuit (IC) chip package module 1 includes a carrier 10, an IC chip 11, a plurality of wires 12, a plurality of pins 13, a cuboid-shaped hollow seal member 14, and a thermal conductor, such as a metal biscuit 15. In addition, the seal member 14 can be other shapes in other embodiments, such as a hemispherical shapes.

A bottom surface of the IC chip 11 is adhered to a top of the carrier 10 via glue. Circuits on an active side opposite to the bottom surface of the IC chip 11 are connected to corresponding first ends of the plurality of pins 13 via the plurality of wires 12. The metal biscuit 15 is laid on the active side of the IC chip 11. The carrier 10, the IC chip 11, and the plurality of wires 12 are located inside of the seal member 14. Second ends opposite to the corresponding first ends of the plurality of pins 13 project out of sidewalls of the seal member 14. An upper portion of the metal biscuit 15 is projected out of a top wall of the seal member 14. A top surface located outside of the seal member 14 of the metal biscuit 15 is at least 0.2mm above a top surface of the top wall of the seal member 14.

When the IC chip 11 works, heat generated by the IC chip 11 is transferred outside through the metal biscuit 15, thus dissipating heat from the IC chip 11 effectively.

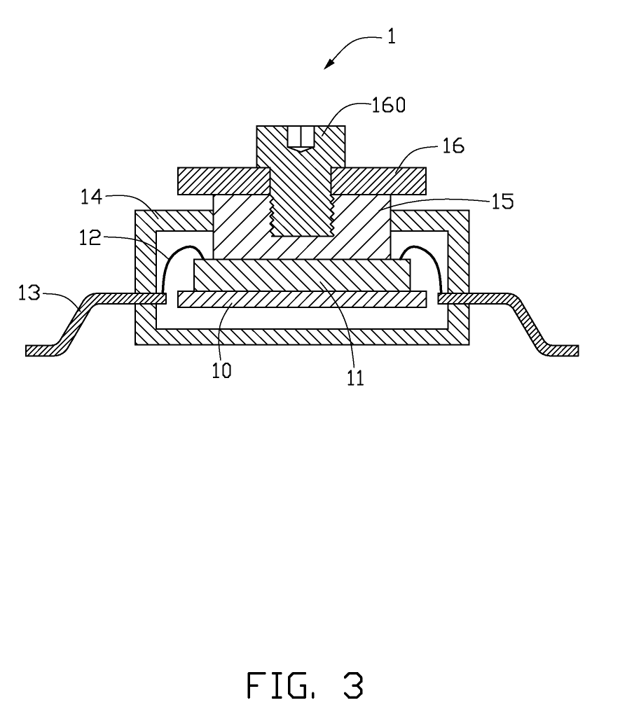

Referring to FIG. 3, in another exemplary embodiment, the IC chip package module 1 can further include a fixing member, such as a screw 160, and a radiator 16. A fixing hole, such as a blind screw hole (not labeled) is defined in a top surface of the metal biscuit 15. The screw 160 is configured to pass through the radiator 16 to engage in the screw hole of the metal biscuit 15 to fix the radiator 16 on the top surface of the metal biscuit 15. When the IC chip 11 works, heat generated by the IC chip 11 is transferred to the radiator 16 via the metal biscuit 15.

In one embodiment, the IC chip package module 1 is packaged in Small outline-8 (SO-8) type. In other embodiments, the IC chip package module 1 can be packaged in other types, such as Discrete Packaging (D-PAK). Furthermore, there can be an interspace between the metal biscuit 15 and the active side of the IC chip 11, which means the metal biscuit 15 is located above the IC chip 11. In addition, the screw hole 150 can be replaced by some other configuration which can fix the radiator 16 on the top surface of the metal biscuit 15, such as a clasp.

The foregoing description of the various inventive embodiments of the disclosure has been presented only for the purposes of illustration and description and is not intended to be exhaustive or to limit the disclosure to the precise forms disclosed. Many modifications and variations are possible in light of the above teaching. The embodiments were chosen and described in order to explain the principles of the disclosure and their practical application so as to enable others of ordinary skill in the art to utilize the disclosure and various embodiments and with various modifications as are suited to the particular use contemplated. Alternately embodiments will become apparent to those of ordinary skill in the art to which the present disclosure pertains without departing from its spirit and scope. Accordingly, the scope of the present disclosure is defined by the appended claims rather than the foregoing description and the various inventive embodiments described therein.

What is claimed is:

1. An integrated circuit (IC) package module comprising:
a carrier;
an IC chip attached on a top surface of the carrier;
a plurality of wires;
a plurality of pins connected to the IC chip via the plurality of wires;
a seal member containing the carrier, the IC chip, and the plurality of wires, wherein at least a part of each of the plurality of pins is projected out of the seal member; and
a thermal conductor located above or located on a top surface of the IC chip, wherein at least a part of the thermal conductor is projected out of the seal member.

2. The IC package module of claim 1, further comprising a radiator attached on a top surface of the thermal conductor.

3. The IC package module of claim 2, wherein the radiator is fixed to the thermal conductor via a fixing member passing through the radiator to engage with the thermal conductor.

4. The IC package module of claim 3, wherein the top surface of the thermal conductor defines a fixing hole, the fixing member is engaged in the fixing hole after passing through the radiator.

5. The IC package module of claim 4, wherein the fixing hole is a blind screw hole.

6. The IC package module of claim 1, wherein the thermal conductor is a metal biscuit.

7. The IC package module of claim 1, wherein the top surface of the IC chip is an active side of the IC chip.

8. The IC package module of claim 1, wherein a top surface of the thermal conductor is at least 0.2mm higher than a top surface of the seal member.
